(19) United States
(12) Patent Application Publication
(10) Pub. No.: US 2024/0372318 A1
(43) Pub. Date: Nov. 7, 2024

(54) OPTOELECTRONIC SEMICONDUCTOR COMPONENT AND METHOD FOR PRODUCING AN OPTOELECTRONIC SEMICONDUCTOR COMPONENT

(71) Applicant: AMS-OSRAM INTERNATIONAL GMBH, Regensburg (DE)

(72) Inventors: Norwin VON MALM, Nittendorf (DE); Dominik SCHOLZ, Bad Abbach (DE)

(21) Appl. No.: 18/689,881

(22) PCT Filed: Sep. 9, 2022
(86) PCT No.: PCT/EP2022/075098

§ 371 Date: Mar. 7, 2024

(30) Foreign Application Priority Data
Sep. 16, 2021 (DE) 10 2021 123 996.6

(51) Int. Cl. H01S 5/024

(52) U.S. Cl. CPC H01S 5/02469

(57) ABSTRACT

An optoelectronic semiconductor component includes a semiconductor body having a first region of a first conductivity, a second region of a second conductivity and an active region. Further, the semiconductor component includes a first metallic heat sink, a second metallic heat sink and a thin film insulation layer. The first heat sink and the second heat sink are arranged on a mounting side of the semiconductor body. The first heat sink electrically contacts the first region. The thin film insulation layer electrically insulates the first heat sink from the second heat sink. The thin film insulation layer is in direct contact with the first heat sink and the second heat sink.

### CROSS-REFERENCE TO RELATED APPLICATIONS

The present application is a U.S. National Stage Application of International Application PCT/EP2022/075098, filed Sep. 9, 2022, and claims the priority of the German Patent Application DE 10 2021 123 996.6, filed Sep. 16, 2021; the entire disclosures of the above-listed applications are hereby explicitly incorporated by reference.

### FIELD

The present disclosure relates to an optoelectronic semiconductor component and a method for producing an optoelectronic semiconductor component.

### SUMMARY

According to at least one embodiment of the present disclosure, an optoelectronic semiconductor component is configured in particular for generating and/or detecting electromagnetic radiation, such as light that is perceptible to the human eye.

According to at least one embodiment of the present disclosure, an optoelectronic semiconductor component has improved cooling and improved mechanical stability.

According to at least one embodiment of the present disclosure relates to a method for the simplified production of an optoelectronic semiconductor component with improved cooling and improved mechanical stability.

According to at least one embodiment, the optoelectronic semiconductor component comprises a semiconductor body having a first region of a first conductivity, a second region of a second conductivity and an active region. In at least one example, the first conductivity differs from the second conductivity. For example, the first region and the second region are formed with a doped semiconductor material. In particular, the active region has a pn junction, a double heterostructure, a single quantum well structure (SQW) or a multi-quantum well structure (MQW) for the generation of radiation or for radiation detection. The semiconductor component is, for example, a photodiode or a luminescence diode, in particular a luminaire or a laser diode.

According to at least one embodiment, the semiconductor body comprises a first contact and a second contact on a mounting side. In particular, the first contact and the second contact are each designed as simply connected elements. The semiconductor body can be contacted exclusively from one side. The mounting side of the semiconductor body is intended in particular for mounting the semiconductor body. In at least one example, the mounting side of the semiconductor body is opposite to an outcoupling side intended for coupling out electromagnetic radiation.

The first contact, for example, is electrically conductively connected to the first region and the second contact is in particular electrically conductively connected to the second region. For example, the first contact completely penetrates the second region and is also electrically insulated from the second region.

According to at least one embodiment, the optoelectronic semiconductor component comprises a first metallic heat sink and a second metallic heat sink. The heat sinks are configured to dissipate heat from the semiconductor body. The heat sinks, in at least one example, are formed with a metal or a metal alloy that has high electrical and thermal conductivity. In at least one example, the heat sinks also contribute to the mechanical stability of the components. For example, the heat sinks are multilayered. In particular, the heat sinks comprise one or more seed layers from a method for their deposition. The first contact and the second contact, in at least one example, are arranged between the semiconductor body and the first and second heat sinks. In particular, the first contact is arranged between the first heat sink and the semiconductor body and the second contact is arranged between the second heat sink and the semiconductor body.

According to at least one embodiment, the optoelectronic semiconductor component comprises a thin film insulation layer. The thin film insulation layer, for example, is formed with an electrically insulating material that has a high dielectric strength. For example, the thin film insulation layer is formed with a dielectric that can be deposited by sputtering or CVD, for example silicon oxide, silicon nitride or tantalum oxide. The thin film insulation layer is particularly multilayered, whereby different layers can be formed with different materials.

According to at least one embodiment of the optoelectronic semiconductor component, the first heat sink and the second heat sink are arranged on the mounting side of the semiconductor body. The arrangement of the heat sinks on the mounting side enables undisturbed coupling out for electromagnetic radiation from the outcoupling side of the semiconductor body opposite the mounting side.

According to at least one embodiment of the optoelectronic semiconductor component, the first heat sink electrically contacts the first region. The first heat sink has a thermal and an electrical contact to the first region. Consequently, an additional electrical connection body can be dispensed with.

According to at least one embodiment of the optoelectronic semiconductor component, the thin film insulation layer electrically insulates the first heat sink from the second heat sink. By means of the thin film insulation layer, for example, a short circuit between the heat sinks is avoided.

According to at least one embodiment of the optoelectronic semiconductor component, the thin film insulation layer is in direct contact with the first heat sink and the second heat sink. In particular, the heat sinks are in positive contact with the thin film insulation layer. The thin film insulation layer thus occupies a particularly small space and enables a high surface occupancy of the heat sinks.

According to at least one embodiment, the optoelectronic semiconductor component comprises
a semiconductor body with a first region of a first conductivity, a second region of a second conductivity and an active region,
a first metallic heat sink and a second metallic heat sink, and
a thin film insulation layer, whereby
the first heat sink and the second heat sink are arranged on a mounting side of the semiconductor body,
the first heat sink makes electrical contact with the first region,
the thin film insulation layer electrically insulates the first heat sink from the second heat sink, and
the thin film insulation layer is in direct contact with the first heat sink and the second heat sink.

Optoelectronic semiconductor components described herein may realize: Improved cooling which can be advantageous for the manufacture of semiconductor components with a higher optical output power in order to avoid damage. The cooling of optoelectronic semiconductor components is, for example, carried out via a mounting side of a semiconductor body and the electrical contacts arranged on it. The highest possible surface area coverage of the mounting side with metallic heat sinks can be advantageous for cooling. Due to limitations in conventional manufacturing processes, a high surface area is difficult to achieve, as a large part of the surface area may be required to electrically insulate the heat sinks from each other.

The optoelectronic semiconductor component described here makes use, among other things, of the idea of arranging a first metallic heat sink on a mounting side of a semiconductor body next to a second metallic heat sink, the heat sinks being electrically insulated from one another by a thin film insulation layer. This results in a particularly high surface occupancy of the mounting side of the semiconductor body with the heat sinks, as the thin film insulation layer requires only a very small area on the mounting side and thus does not significantly impair the dissipation of heat from the semiconductor body. For manufacturing an optoelectronic semiconductor component with a thin film insulation layer, a method is further disclosed which uses sequential deposition of the first and second heat sinks one after the other.

According to at least one embodiment of the optoelectronic semiconductor component, the thin film insulation layer has a thickness of at most 1 μm, for example, at most 0.3 μm, for example, at most 100 nm. In at least one example, the thin film insulation layer has a sufficiently large thickness to ensure a sufficiently high dielectric strength to electrically insulate the first heat sink from the second heat sink during operation of the optoelectronic semiconductor component. The thickness of the thin film insulation layer is to be understood here and in the following as its expansion perpendicular to its main direction of extension. A small thickness of the thin film insulation layer enables a high surface occupancy of the mounting side of the semiconductor body with the first and second metallic heat sink.

In particular, the thin film insulation layer has an aspect ratio of at least 1/10, for example, at least 1/50, or at least 1/100. Aspect ratio is understood here and in the following as a ratio of the thickness of an element to its height. In other words, an extension of the thin film insulation layer along its main direction of extension is at least 10 times greater than its thickness.

According to at least one embodiment of the optoelectronic semiconductor component, a first distance between the first heat sink and the second heat sink is at most 1 μm, for example, at most 0.3 μm and for example, at most 100 nm. A small distance between the heat sinks enables a high surface occupancy of the mounting side of the semiconductor body with the metallic material of the first and second heat sink. In this way, an efficient cooling of the semiconductor body can be achieved. In particular, the distance between the first heat sink and the second heat sink corresponds to a thickness of the thin film insulation layer.

According to at least one embodiment of the optoelectronic semiconductor component, metal pads are arranged on the first heat sink and the second heat sink. The metal pads are particularly suitable for soldering of the optoelectronic semiconductor component. In at least one example, the metal pads are formed with gold or a gold-containing alloy or layer sequence. For example, the metal pads are formed from a composite of several layers, whereby layers of different materials are included.

According to at least one embodiment of the optoelectronic semiconductor component, a second distance between the metal pads is at least 180 μm. A distance of at least 180 μm avoids, for example, a short circuit during solder mounting of the semiconductor component. In particular, the second distance is greater than the first distance.

According to at least one embodiment of the optoelectronic semiconductor component, the first heat sink and the second heat sink have a height of between 20 μm and 500 μm, such as, for example, between 100 μm and 150 μm. The height of the heat sinks is to be understood here and in the following as an expansion in a direction transverse to the main extension plane of the semiconductor body. Heat sinks designed in this way have a sufficient thermal conductivity to efficiently cool the semiconductor body. In particular, the heat sinks serve to mechanically stabilize the optoelectronic semiconductor component. Further mechanically supporting components can thus be dispensed with.

According to at least one embodiment of the optoelectronic semiconductor component, the first heat sink and the second heat sink have projections that extend at least partially into the respective opposite heat sink. In other words, the first heat sink and the second heat sink are interlocked in a comb-like manner in a plan view. Due to the comb-like interlocking, the heat sinks have an increased mechanical stability. Despite the comb-like interlocking, the first heat sink remains electrically insulated from the second heat sink. The first heat sink and the second heat sink, in at least one example, are not in direct contact with each other and are spaced apart at each point. In particular, the first heat sink has a distance from the second heat sink that corresponds to the thickness of the thin film insulation layer.

According to at least one embodiment of the optoelectronic semiconductor component, the second heat sink contacts the second region electrically. An additional electrical contact for the second region can thus be dispensed with. In particular, the second heat sink makes thermal and electrical contact with the second region.

According to at least one embodiment of the optoelectronic semiconductor component, a via extends through the second heat sink and contacts the second region. In at least one example, the via is formed with the metallic material of the first heat sink. In particular, the via can have a smaller lateral expansion than the first heat sink. In at least one example, the via penetrates the second heat sink completely.

According to at least one embodiment of the optoelectronic semiconductor component, the via is electrically insulated via the second heat sink. In at least one example, the second heat sink is therefore potential-free. This enables particularly effective electrical insulation between the first heat sink and the second heat sink. In particular, the second heat sink is in thermal contact with the semiconductor body.

According to at least one embodiment of the optoelectronic semiconductor component, a cross-sectional area of the first heat sink and the second heat sink each does not increase along its entire extension in a direction transverse to a main extension plane of the semiconductor body. By means of the manufacturing method described here, first and second heat sinks with a specific geometry are manufactured in particular. In particular, the first and second heat sinks have a characteristic course of a cross-sectional area along their extension in a direction transverse to a main extension plane of the semiconductor body. In particular, the cross-sectional area of the first heat sink is constant along its entire extension in a direction transverse to a main extension plane of the semiconductor body. In at least one example, the cross-sectional area of the second heat sink is constant along its entire extension in a direction transverse to a main extension plane of the semiconductor body.

According to at least one embodiment of the optoelectronic semiconductor component, the first heat sink and the second heat sink do not overlap in a plan view. In particular, a top view describes a view from a direction transverse to the main extension plane of the semiconductor body. The first heat sink and the second heat sink are arranged in particular at a small distance from each other, but, for example, do not overlap at any point along their entire extension in a plan view.

A method for producing an optoelectronic semiconductor component is further disclosed. The optoelectronic component can be manufactured in particular by means of a method described herein. In other words, all features disclosed in connection with the method for producing an optoelectronic semiconductor component are also disclosed for the optoelectronic semiconductor component and vice versa.

According to at least one embodiment, the method comprises providing a semiconductor body having a first region of a first conductivity, a second region of a second conductivity and an active region, wherein the semiconductor body has a first contact and a second contact on a mounting side. The first contact is, for example, used for the electrical connection of the first region. The second contact is, for example, used for the electrical connection of the second region.

According to at least one embodiment, the method comprises depositing a first heat sink on the mounting side of the semiconductor body, wherein the first heat sink electrically connects the first region. For example, the first heat sink and the second heat sink are deposited galvanically. By means of galvanic deposition, the heat sinks can be deposited with particularly high deposition rates and particularly large deposition thicknesses.

According to at least one embodiment, the method comprises depositing a thin film insulation layer on the mounting side, wherein the thin film insulation layer covers at least one side face of the first heat sink facing the second contact. In this way, a short circuit between the first heat sink and a second heat sink subsequently arranged on the second contact can be avoided.

According to at least one embodiment, the method comprises depositing a second heat sink on the mounting side of the semiconductor body. The second heat sink is, in at least one example, deposited using a galvanic deposition method.

According to at least one embodiment, the method includes:
A) Providing a semiconductor body having a first region of a first conductivity, a second region of a second conductivity and an active region, wherein the semiconductor body has a first contact and a second contact on a mounting side,
B) Depositing a first heat sink on the mounting side of the semiconductor body, the first heat sink electrically connecting the first region,
C) Depositing a thin film insulation layer on the mounting side, wherein the thin film insulation layer covers at least one side face of the first heat sink facing the second contact, and
D) Depositing a second heat sink on the mounting side of the semiconductor body.

In at least one example, the process is carried out in their alphabetical order.

According to at least one embodiment of the method, an electrically conductive first seed layer is applied to the mounting side of the semiconductor body before the first heat sink is deposited. The first seed layer is deposited, for example, by sputtering or CVD.

According to at least one embodiment of the method, the first heat sink and the second heat sink are embedded in an electrically insulating molding compound. The heat sinks are embedded using a molding method, for example. The insulating molding compound is formed, for example, with a polymer, in particular an epoxy. The insulating molding compound protects the first heat sink and the second heat sink from harmful external environmental influences in particular.

According to at least one embodiment of the method, the second heat sink is deposited after the thin film insulation layer has been deposited. Sequential deposition of the second heat sink after the first heat sink enables a particularly small distance between the heat sinks.

According to at least one embodiment of the method, the second heat sink is deposited with a lower height than the first heat sink. In particular, the second heat sink is deposited with a height of at least 10 μm less than the first heat sink. If the second heat sink is deposited with a lower height than the first heat sink, a short circuit between the first heat sink and the second heat sink can be avoided during galvanic deposition.

According to at least one embodiment of the method, a contact body is deposited on the second heat sink. The contact body, in at least one, is formed with an electrically conductive material. In particular, the contact body is formed with the same material as the second heat sink. The contact body is designed, for example, to compensate for a different height of the second heat sink relative to the first heat sink. A flat mounting surface for the optoelectronic semiconductor component can be produced in this way.

According to at least one embodiment of the method, the second contact is exposed after deposition of the thin film insulation layer and before deposition of the second heat sink. In at least one example, the second contact is exposed by means of an etching process. When exposing the second contact, an electrically insulating material is at least partially removed from a side of the second contact facing away from the semiconductor body. This can enable electrical contacting of the second contact.

According to at least one embodiment of the method, a via is deposited on the mounting side of the semiconductor body before the second heat sink is deposited. The via is, in at least one example, formed with the material of the first heat sink. In particular, the via is electrically conductively connected to the second contact.

According to at least one embodiment of the method, metal pads are deposited on the side of the first heat sink and the second heat sink opposite the semiconductor body. For example, the metal pads are deposited using a galvanic deposition method. Particularly dense metal pads can be produced in this way, which have high electrical and thermal conductivity.

An optoelectronic semiconductor component described here is particularly suitable for use as a high-power light-emitting diode for application in motor vehicle headlights or projection lighting.

### BRIEF DESCRIPTION OF THE DRAWINGS

Further configurations and exemplary embodiments of the optoelectronic semiconductor component are shown in connection with the following figures.

FIGS. 1A to 1G schematic sectional views of an optoelectronic semiconductor component described herein in various steps of a method described herein for its production according to a first exemplary embodiment,

FIGS. 2A to 2G schematic sectional views of an optoelectronic semiconductor component described herein in various steps of a method described herein for its production according to a second exemplary embodiment,

FIGS. 3A to 3H schematic sectional views of an optoelectronic semiconductor component described herein in various steps of a method described herein for its production according to a third exemplary embodiment, and

FIGS. 4A to 4F schematic top views of optoelectronic semiconductor components described herein according to a fourth, fifth, sixth, seventh, eighth and ninth embodiment.

Elements that are identical, similar or have the same effect are marked with the same reference signs in the figures. The figures and the proportions of the elements shown in the figures are not to be regarded as being to scale. Rather, individual elements may be shown in exaggerated size for better visualization and/or better comprehensibility.

All embodiments of the method described here for manufacturing an optoelectronic semiconductor component 1 are, in at least one example, carried out in parallel on a plurality of semiconductor components 1 in a wafer composite. Subsequently, the plurality of optoelectronic semiconductor components 1 can be singulated at separating lines provided for this purpose.

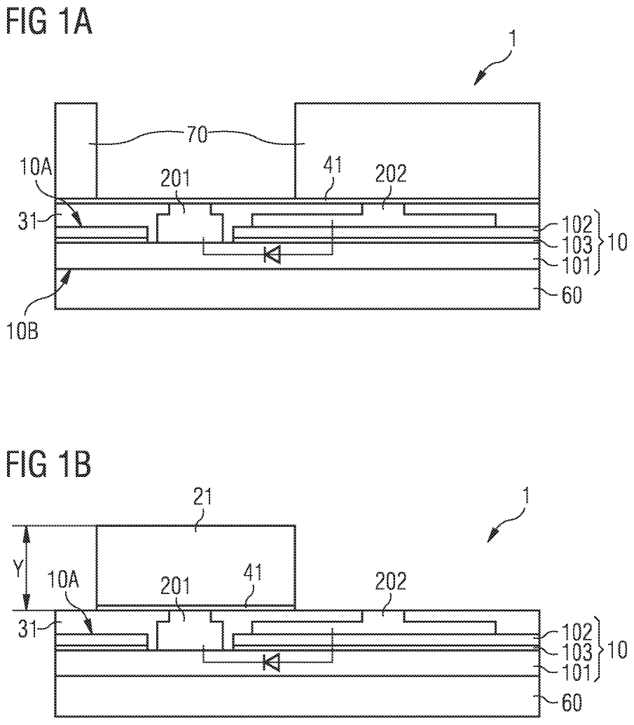

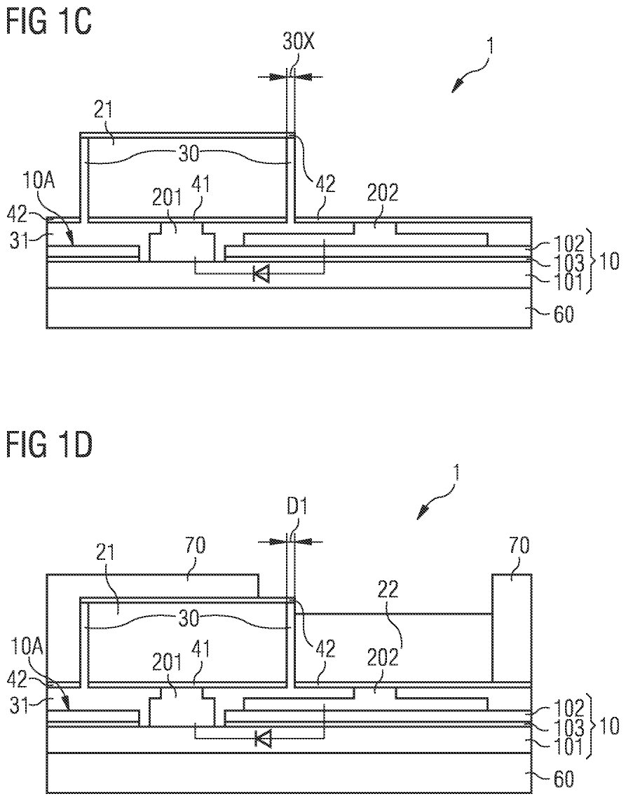

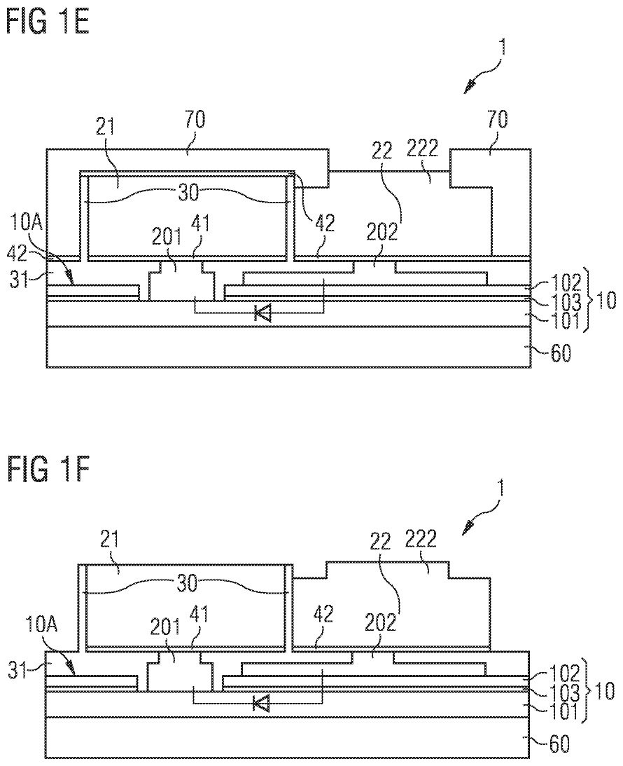

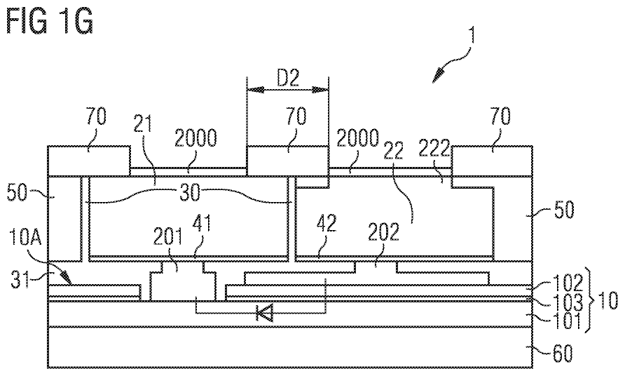

FIGS. 1A to 1G show schematic sectional views of an optoelectronic semiconductor component 1 described herein in various steps of a method described herein for its production according to a first exemplary embodiment.

FIG. 1A shows the provision of a semiconductor body 10 on a carrier 60. The semiconductor body 10 comprises a first region 101 of a first conductivity, a second region 102 of a second conductivity and an active region 103 which is configured to emit electromagnetic radiation. The first conductivity is an n-type conductivity and the second conductivity is a p-type conductivity. The semiconductor body 10 has a mounting side 10A, which is provided for mounting the semiconductor body 10 on further elements.

Furthermore, the semiconductor body 10 comprises a first contact 201 and a second contact 202 on the mounting side 10A. The semiconductor body 10 is thus contacted exclusively from one side. The mounting side 10A is opposite an outcoupling side 10B provided for coupling out electromagnetic radiation.

The first contact 201 is electrically conductively connected to the first region 101 and the second contact 202 is electrically conductively connected to the second region 102. The first contact 201 completely penetrates the second region 102 and is further electrically insulated from the second region 102. The first contact 201 is electrically insulated from the second contact 202 by a passivation 31. The first contact 201 is at least in places in direct contact with the first region 101. The second contact 202 is at least in places in direct contact with the second region 102.

A first seed layer 41 is applied to the mounting side 10A of the semiconductor body 10. The first seed layer 41 is formed with an electrically conductive material that enables particularly good overmolding of the semiconductor body 10. For example, the first seed layer 41 is formed with one of the following materials TiAu, PtAu, TiCu, PtCu. For example, the first seed layer 41 is deposited on the semiconductor body 10 by means of sputtering. A photoresist layer 70 is arranged downstream of the seed layer 41. The photoresist layer 70 is structured in such a way that the first contact 201 is free of the photoresist layer 70.

In the process step shown in FIG. 1B, a first heat sink 21 is galvanically deposited. The photoresist layer 70 is then removed. The first seed layer 41 is removed in the regions next to the first heat sink 21. The first heat sink 21 has a height Y between 20 μm and 500 μm, for example, between 100 μm and 150 μm. The height Y is to be understood as a vertical extension of the first heat sink 21 in a direction transverse to a main extension plane of the semiconductor body 10.

The process step shown in FIG. 1C shows the deposition of a thin film insulation layer 30. The thin film insulation layer 30 is deposited on the first heat sink 21 in a conformal manner and then anisotropically etched. In particular, the thin film insulation layer 30 is formed with a dielectric that can be deposited by CVD. The thin film insulation layer 30 thus remains on the side faces of the first heat sink 21. The thin film insulation layer 30 has a thickness 30X of at most 1 μm, for example, of at most 0.3 μm and for example, of at most 100 nm. The thin film insulation layer 30 has an aspect ratio of at least 1/10. In other words, an extension of the thin film insulation layer 30 in a direction transverse to its thickness 30X is at least 10 times as large as its thickness 30X.

Subsequently, a second seed layer 42 is deposited. In particular, the second seed layer 42 is deposited anisotropically. To avoid short circuits between the first heat sink 21 and the second contact 202 due to residues of the second seed layer 42 on the thin film insulation layer 30, further process steps may be necessary.

In an example, residues of the second seed layer 42 are removed from the thin film insulation layer 31 using a wet-chemical cleaning step. Alternatively, the thin film insulation layer 30 is removed after deposition of the second seed layer 42 and reapplied. The thin film insulation layer 42 is removed, for example, using a wet chemical etching process. The thin film insulation layer 30 is reapplied in the same way as the first deposition of the thin film insulation layer in a conformal deposition process with a subsequent anisotropic etching process.

In the process step shown in FIG. 1D, a photoresist layer 70 is at least partially applied to the first heat sink 21 and structured. In an example, the second contact 202 and an edge of the second heat sink facing the second contact 202 remain free of the photoresist layer 70. Optionally, a later region selected as a separation line is covered by the photoresist layer 70 in order to achieve a simple separation of adjacent optoelectronic semiconductor components 1. Subsequently, a second heat sink 22 is deposited over the second contact 202. In particular, the second heat sink 22 is galvanically deposited. No further material is deposited on the first heat sink 21 due to the lack of electrical contacting. The first contact 201 and the second contact 202 are arranged between the semiconductor body 10 and the first and second heat sinks 21, 22. The first contact 201 is arranged between the first heat sink 21 and the semiconductor body 10, and the second contact 22 is arranged between the second heat sink 22 and the semiconductor body 10.

In particular, the second heat sink 22 is deposited with a lower height Y than the first heat sink 21. For example, the second heat sink has a height Y that is at least 10 μm lower than the first heat sink 21. The first heat sink 21 and the second heat sink are in direct contact with the thin film insulation layer 30. Only the thin film insulation layer 30 is arranged between the first heat sink 21 and the second heat sink 22.

By means of this manufacturing method, first and second heat sinks 21, 22 are manufactured with a specific geometry. In particular, the first and second heat sinks 21, 22 have a characteristic course of a cross-sectional area along their extension in a direction transverse to a main extension plane of the semiconductor body 10. A cross-sectional area of the first heat sink 21 does not increase along its entire extension in a direction transverse to a main extension plane of the semiconductor body 10. A cross-sectional area of the second heat sink 22 does not increase along its entire extension in a direction transverse to a main extension plane of the semiconductor body 10.

The cross-sectional area of the first heat sink 21 along its entire extension in a direction transverse to a main extension plane of the semiconductor body 10 is constant. The cross-sectional area of the second heat sink 22 along its entire extension in a direction transverse to a main extension plane of the semiconductor body 10 is constant.

The first heat sink 21 and the second heat sink 22 do not overlap in a plan view. A plan view describes in particular a view from a direction transverse to the main extension plane of the semiconductor body 10. The first heat sink 21 and the second heat sink 22 are arranged in particular at a small distance from one another, but, in at least one example, do not overlap at any point along their entire extension in plan view.

The process step shown in FIG. 1E shows a deposition of a photoresist layer 70 that is structured such that a portion of the second heat sink 22 remains free of the photoresist layer 70. A contact body 222 is deposited on the second heat sink 22 in the opening of the photoresist layer 70. The contact body 222 is formed with an electrically conductive material. In particular, the contact body 222 is formed with the same material as the second heat sink 22. The contact body is designed to compensate for the different height of the second heat sink 22 relative to the first heat sink 21. A flat mounting surface for the optoelectronic semiconductor component 1 can thus be produced.

The process step shown in FIG. 1F shows a removal of the second seed layer 42. The second seed layer 42 is removed, for example, by wet chemical means. An electrical short circuit between the first heat sink 21 and the second heat sink 22 can thus be avoided more easily.

In the process step shown in FIG. 1G, an electrically insulating molding compound 50 is arranged laterally around the first heat sink 21 and the second heat sink 22. The electrically insulating molding compound 50 is formed, for example, with a polymer, in particular an epoxy. By means of the electrically insulating molding compound 50, the optoelectronic semiconductor component 1 is particularly well protected from harmful environmental influences. For example, the heat sinks 21, 22 are completely embedded in the molding compound 50. The molding compound 50 is then ground back, for example, in order to expose and planarize the heat sinks 21, 22 again.

Furthermore, a photoresist layer 70 is applied to the first heat sink 21 and the second heat sink 22, each of which has an opening on the first heat sink and the second heat sink 22. The openings of the photoresist layer 70 in at least one example have a second distance D2 of at least 180 μm from one another. Metal pads 2000, which also have a second distance D2 of at least 180 μm from one another, are deposited in the openings of the photoresist layer 70. The metal pads 2000 are formed with an electrically conductive material that enables solder mounting of the optoelectronic semiconductor component 1. A minimum distance of 180 μm between the metal pads 2000 is helpful in order to avoid short circuits during solder mounting.

The photoresist layer 70 is then removed again to enable easy assembly of the optoelectronic semiconductor component 1.

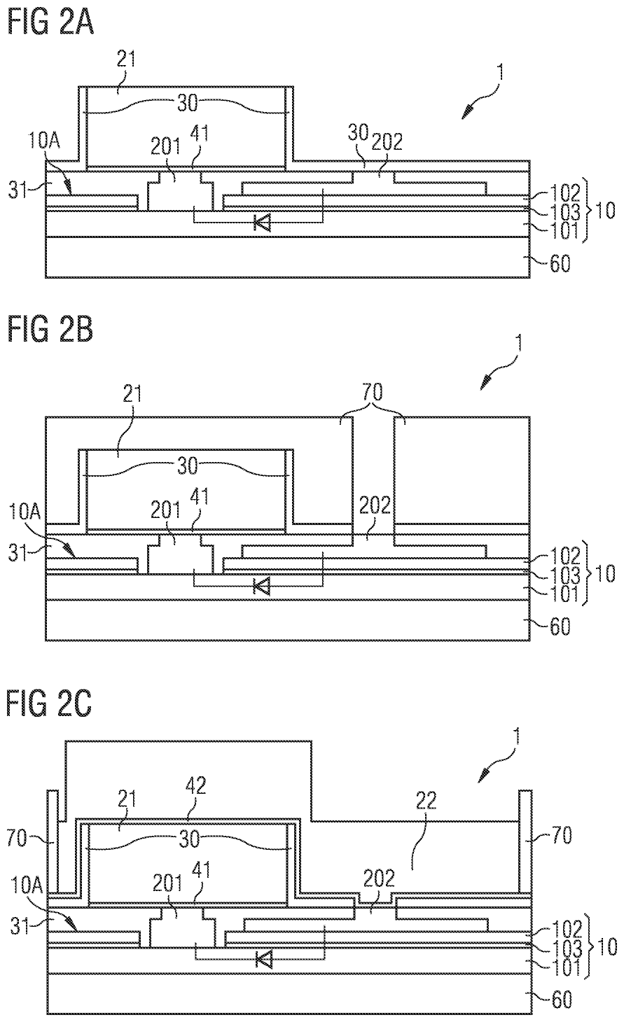

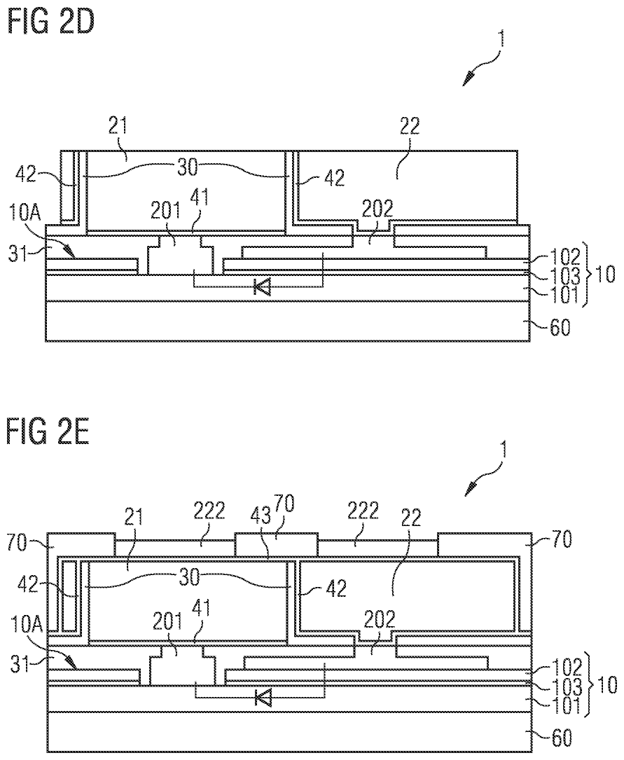

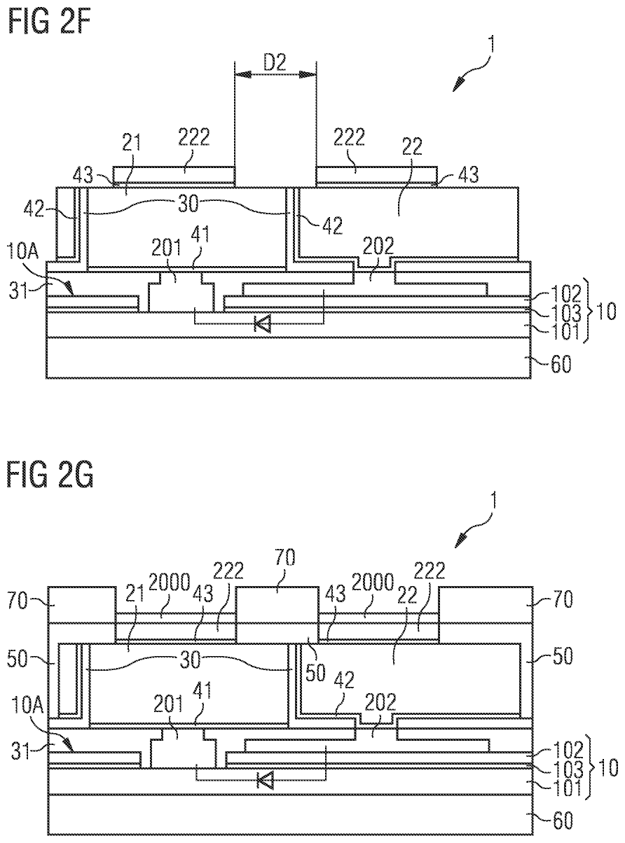

FIGS. 2A to 2G show schematic sectional views of an optoelectronic semiconductor component 1 described herein in various steps of a method described herein for its production according to a second exemplary embodiment.

For example, the component provided in FIG. 2A is manufactured using a method according to the steps described in FIGS. 1A and 1B.

FIG. 2A shows a deposition of a thin film insulation layer 30 on the first heat sink 21 after the first seed layer 41 has been removed in regions adjacent to the first heat sink 21. The thin film insulation layer 30 is conformally deposited and covers the second contact 202. Subsequently, the first heat sink 21 is exposed by at least partially removing the thin film insulation layer 30. For example, the partial removal of the thin film insulation layer 30 is performed by a grinding process.

In the step shown in FIG. 2B, a photoresist layer 70 is applied and structured. An opening of the photoresist layer at least partially covers the second contact 202. The thin film insulation layer 30 deposited over the second contact 202 is removed to expose the second contact 202. In at least one example, the thin film insulation layer 30 is removed using an etching process. The photoresist layer 70 is then removed.

FIG. 2C shows a step in which a second seed layer 42 is deposited over the first heat sink 21 and the second contact 202. The second seed layer 42 is formed, for example, with the same material as the first seed layer 41. A photoresist layer 70 is then applied and structured. Optionally, the photoresist layer 70 is applied to lateral edges of the optoelectronic semiconductor component 1 in order to simplify subsequent singulation of a plurality of semiconductor components 1 at a separation line.

Subsequently, a second heat sink 22 is deposited. In particular, the second heat sink 22 is deposited galvanically. The second heat sink 22 extends beyond the first heat sink 21 along the second seed layer 42. The second seed layer 42 is formed, for example, with the same material as the second heat sink 22. The second seed layer 42 is at least sectionally a part of the second heat sink 22. The first heat sink 21 and the second heat sink 22 are electrically short-circuited.

The photoresist layer 70 is removed after the second heat sink 22 has been deposited. For example, the second seed layer 42 can then also be removed in the regions next to the first heat sink 21 and the second heat sink 22.

FIG. 2D shows a step in which the electrical short circuit between the first heat sink 21 and the second heat sink 22 is eliminated by partially removing the second heat sink 22. For example, the second heat sink 22 and a portion of the second seed layer 42 are removed by a grinding process to electrically isolate the two heat sinks 21, 22 from each other. This achieves an equalization of the height Y of the second heat sink 22 to a height Y of the first heat sink 21. The first heat sink 21 and the second heat sink 22 are each in direct contact with the thin film insulation layer 30.

In the step shown in FIG. 2E, a third seed layer 43 is applied to the first heat sink 21 and the second heat sink 22. For example, the third seed layer 43 is formed with the same material as the first seed layer 41 and/or the second seed layer 42. Subsequently, a photoresist layer 70 is applied and contact bodies 222 are deposited in openings of the photoresist layer 70. The contact bodies 222 have a second distance D2 of at least 180 μm from one another.

FIG. 2F shows a further step in which the third seed layer 43 and the photoresist layer 70 are removed after the contact bodies 222 have been deposited. For example, the heat sinks 21, 22 are completely embedded in an electrically insulating molding compound 50. The molding compound 50 is then ground back, for example, in order to expose and planarize the heat sinks 21, 22 again.

In the step shown in FIG. 2G, the electrically insulating molding compound 50 is arranged around the first heat sink 21 and the second heat sink 22. A photoresist layer 70 is then applied to the heat sinks 21, 22 and metal pads 2000 are deposited on the contact bodies 222 in openings in the photoresist layer 70. The photoresist layer 70 is removed after the metal pads 2000 have been deposited.

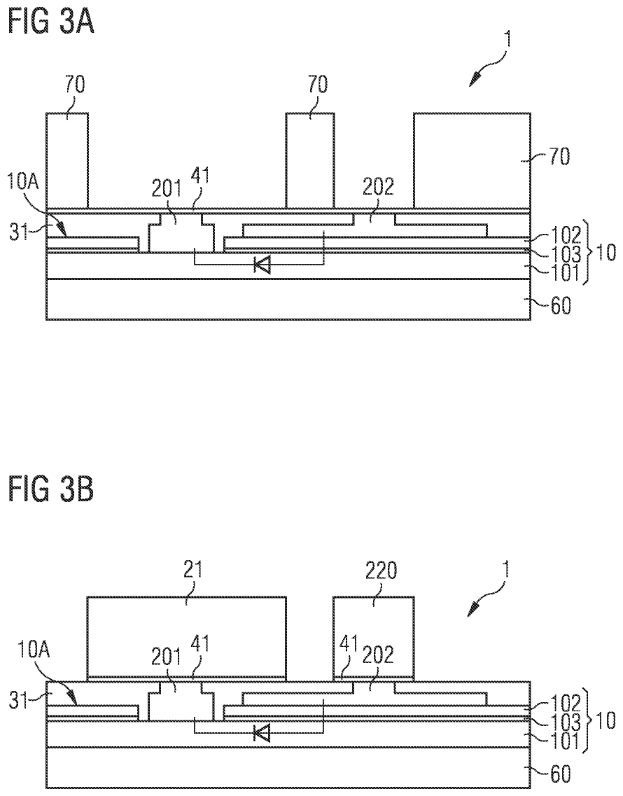

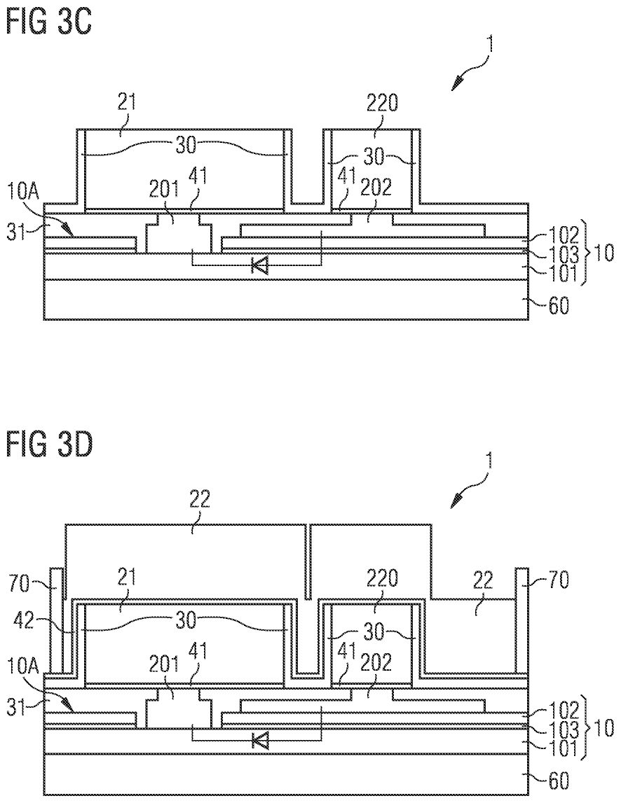

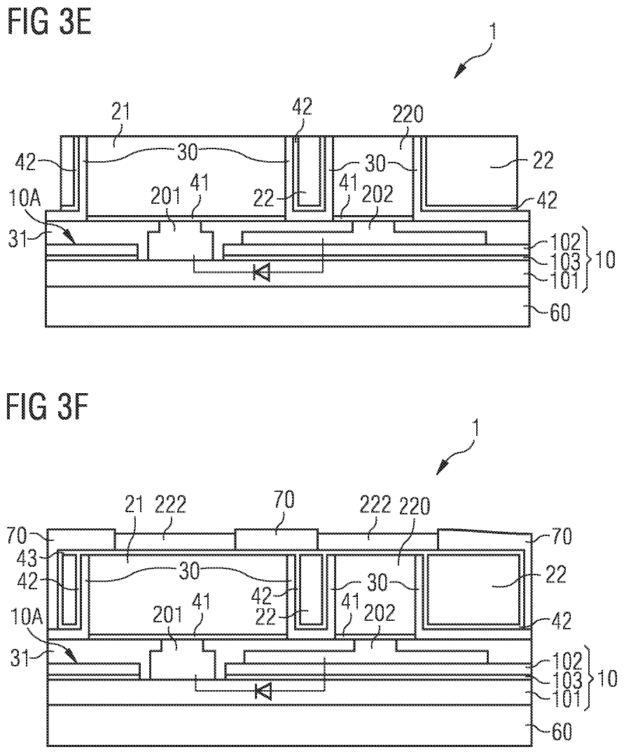

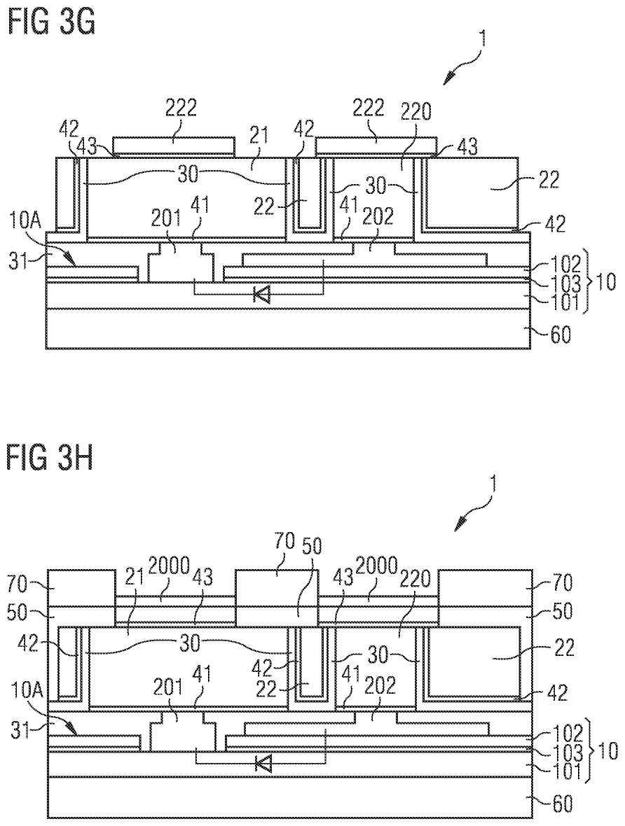

FIGS. 3A to 3H show schematic sectional views of an optoelectronic semiconductor component 1 described herein in various steps of a method described herein for its production according to a third exemplary embodiment.

FIG. 3A shows a step in which a semiconductor body 10 is provided. The semiconductor body 10 corresponds to the semiconductor body 10 shown in FIG. 1A according to the first exemplary embodiment.

A first seed layer 41 is deposited on the mounting side 10A of the semiconductor body 10. A photoresist layer 70 is arranged on the first seed layer 41. The photoresist layer 70 is structured such that it has an opening above each of the first contact 201 and the second contact 202 of the semiconductor body 10.

In the step shown in FIG. 3B, a first heat sink and a via 220 are deposited in the openings of the photoresist layer 70. In at least one example, the deposition of the via 220 and the first heat sink 21 is performed galvanically. In particular, the via 220 and the first heat sink 21 are formed with the same material.

The photoresist layer 70 and the first seed layer 31 are then removed.

In the step shown in FIG. 3C, a thin film insulation layer 30 is deposited on the first heat sink 21 and the via 220. In at least one example, the thin film insulation layer 30 is deposited in a conformal manner. Subsequently, a partial removal of the thin film insulation layer 30 is performed on the side of the first heat sink 21 and the via 222 facing away from the semiconductor body 10.

The partial removal of the thin film insulation layer 30 is in at least one example carried out using a grinding process.

FIG. 3D shows a step in which a second seed layer 42 is deposited over the first heat sink 21 and the via 220. The second seed layer 42 is formed, for example, with the same material as the first seed layer 41. A photoresist layer 70 is then applied and structured. Optionally, the photoresist layer 70 is applied to lateral edges of the optoelectronic semiconductor component 1 in order to simplify subsequent singulation of a plurality of semiconductor components 1 at a separation line.

Subsequently, a second heat sink 22 is deposited. In particular, the second heat sink 22 is deposited galvanically. The second heat sink 22 extends, beyond the first heat sink 21 and the via 220, along the second seed layer 42. The second seed layer 42 is formed, for example, with the same material as the second heat sink 22. The second seed layer 42 is at least sectionally a part of the second heat sink 22. The first heat sink 21, the via 220 and the second heat sink 22 are electrically short-circuited.

The photoresist layer 70 is removed after the second heat sink 22 has been deposited. For example, the second seed layer 42 can then also be removed in the regions next to the first heat sink 21 and the second heat sink 22.

In the step shown in FIG. 3E, the electrical short between the first heat sink 21, the via 220 and the second heat sink 22 is eliminated by partially removing the second heat sink 22. For example, the second heat sink 22 and a portion of the second seed layer 42 are removed by a grinding process to electrically isolate the two heat sinks 21, 22 and the via 220 from each other. This achieves an equalization of the height Y of the second heat sink 22 and the via 220 to a height Y of the first heat sink 21. The first heat sink 21 and the second heat sink 22 are each in direct contact with the thin film insulation layer 30.

By means of this manufacturing method, first and second heat sinks 21, 22 are manufactured with a specific geometry. In particular, the first and second heat sinks 21, 22 have a characteristic course of a cross-sectional area along their extension in a direction transverse to a main extension plane of the semiconductor body 10. A cross-sectional area of the first heat sink 21 does not increase along its entire extension in a direction transverse to a main extension plane of the semiconductor body 10. A cross-sectional area of the second heat sink 22 does not increase along its entire extension in a direction transverse to a main extension plane of the semiconductor body 10.

The cross-sectional area of the first heat sink 21 along its entire extension in a direction transverse to a main extension plane of the semiconductor body 10 is constant. The cross-sectional area of the second heat sink 22 along its entire extension in a direction transverse to a main extension plane of the semiconductor body 10 is constant.

In the step shown in FIG. 3F, a third seed layer 43 is applied to the first heat sink 21, the via 220 and the second heat sink 22. For example, the third seed layer 43 is formed with the same material as the first seed layer 41 and/or the second seed layer 42. Subsequently, a photoresist layer 70 is applied and contact bodies 222 are deposited in openings of the photoresist layer 70. At least one contact body 222 overlaps at least partially with the first heat sink 21 in a plan view. At least one contact body 222 overlaps at least partially with the via 220 in a plan view. For example, a lateral extent of a contact body 222 arranged over the via 220 is smaller than or equal to a lateral extent of the via 220.

The contact bodies 222 have a second distance D2 of at least 180 μm from one another. The third seed layer 43 and the photoresist layer 70 are removed after the contact bodies 222 have been deposited.

FIG. 3H shows a step in which an electrically insulating molding compound 50 is arranged around the first heat sink 21 and the second heat sink 22. For example, the heat sinks 21, 22 are completely embedded in an electrically insulating molding compound 50. In particular, the molding compound 50 is then ground back to expose and planarize the heat sinks 21, 22 again. A photoresist layer 70 is then applied to the heat sinks 21, 22 and metal pads 2000 are deposited on the contact bodies 222 in openings in the photoresist layer 70. The photoresist layer 70 is removed after the metal pads 2000 have been deposited.

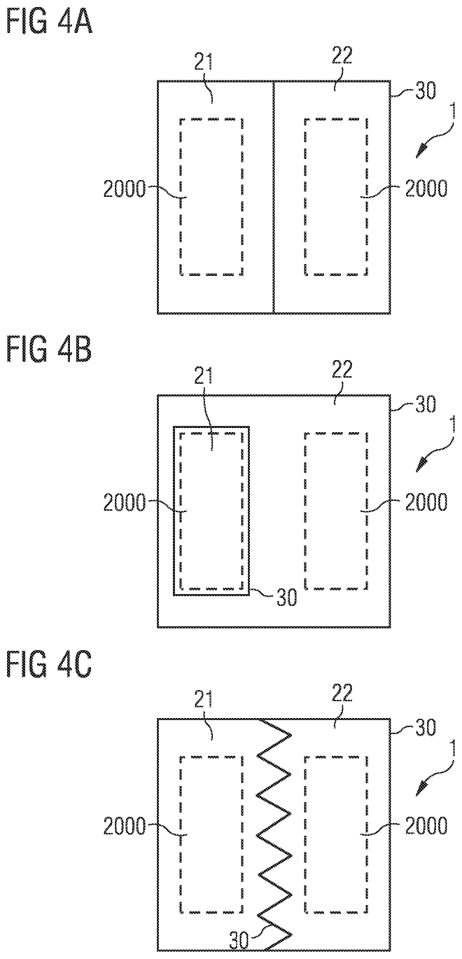

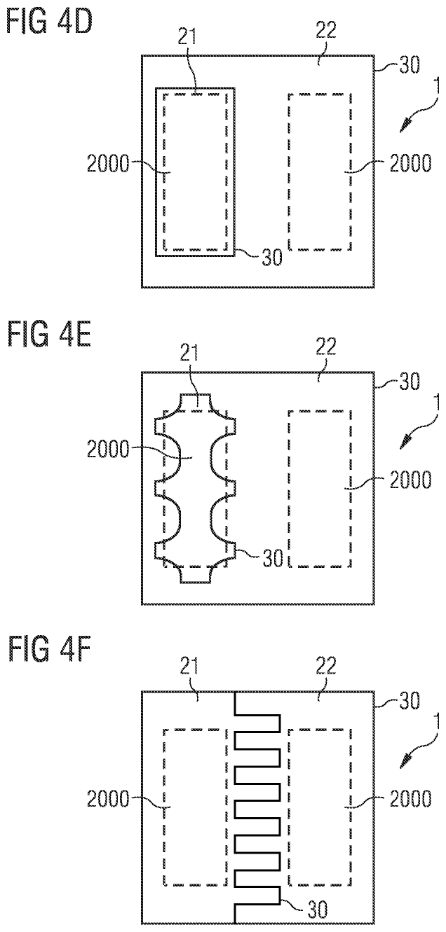

FIGS. 4A to 4F show schematic top views of optoelectronic semiconductor components 1 described herein according to a fourth, fifth, sixth, seventh, eighth and ninth exemplary embodiment.

FIG. 4A shows an optoelectronic semiconductor component 1 according to a fourth exemplary embodiment, comprising a first heat sink 21, a second heat sink 22. Heat sinks 21, 22 are each provided with a metal pad 2000. A thin film insulation layer 30 extends circumferentially around the heat sinks 21, 22 and in a straight line between the two heat sinks 21, 22. Consequently, the first heat sink 21 is electrically insulated from the second heat sink 22 by means of the thin film insulation layer 30. Furthermore, both heat sinks 21, 22 are electrically insulated from the elements surrounding them. A distance between the first heat sink 21 and the second heat sink 22 corresponds in particular to a thickness 30X of the thin film insulation layer 30.

The first heat sink 21 does not overlap with the second heat sink 22 in the top view of the optoelectronic semiconductor component 1 shown in FIG. 4A.

FIG. 4B shows an optoelectronic semiconductor component 1 according to a fifth exemplary embodiment, comprising a first heat sink 21, a second heat sink 22. Heat sinks 21, 22 are each provided with a metal pad 2000. A thin film insulation layer 30 extends circumferentially around the second heat sink 22 and circumferentially around the first heat sink 21. The first heat sink 21 has the same lateral extent as the metal pad 2000 arranged above and is arranged congruent with the metal pad 2000. A distance between the first heat sink 21 and the second heat sink 22 corresponds in particular to a thickness 30X of the thin film insulation layer 30.

The first heat sink 21 is therefore electrically insulated from the second heat sink 22 by means of the thin film insulation layer 30. Furthermore, both heat sinks 21, 22 are electrically insulated from the elements surrounding them. The insulation surrounding the first heat sink 21 is well protected against external environmental influences. A short circuit between the two heat sinks 21, 22 can thus be avoided particularly efficiently.

The first heat sink 21 does not overlap with the second heat sink 22 in the top view of the optoelectronic semiconductor component 1 shown in FIG. 4B.

FIG. 4C shows an optoelectronic semiconductor component 1 according to a sixth exemplary embodiment, comprising a first heat sink 21, a second heat sink 22. Heat sinks 21, 22 are each provided with a metal pad 2000. A thin film insulation layer 30 extends circumferentially around the heat sinks 21, 22 and in a zigzag line between the two heat sinks 21, 22. The first heat sink 21 is thus electrically insulated from the second heat sink 22 by means of the thin film insulation layer 30. Furthermore, both heat sinks 21, 22 are electrically insulated from the elements surrounding them. A distance between the first heat sink 21 and the second heat sink 22 corresponds in particular to a thickness 30X of the thin film insulation layer 30.

The first heat sink 21 and the second heat sink 22 each have projections that extend at least partially into the respective opposite heat sinks 21, 22. In other words, the first heat sink 21 and the second heat sink 22 are interlocked in a comb-like manner in a plan view. Due to a comb-like interlocking, the heat sinks 21, 22 have an increased mechanical stability.

The first heat sink 21 does not overlap with the second heat sink 22 in the top view of the optoelectronic semiconductor component 1 shown in FIG. 4C.

FIG. 4D shows an optoelectronic semiconductor component 1 according to a seventh exemplary embodiment, comprising a first heat sink 21, a second heat sink 22. Heat sinks 21, 22 are each provided with a metal pad 2000. A thin film insulation layer 30 extends circumferentially around the second heat sink and circumferentially around the first heat sink. The first heat sink 21 has a larger lateral extension than the metal pad 2000 arranged above it. The centers of the first heat sink 21 and the metal pad 2000 arranged above it are congruent. A distance between the first heat sink 21 and the second heat sink 22 corresponds in particular to a thickness 30X of the thin film insulation layer 30.

The first heat sink 21 is therefore electrically insulated from the second heat sink 22 by means of the thin film insulation layer 30. Furthermore, both heat sinks 21, 22 are electrically insulated from the elements surrounding them. The insulation surrounding the first heat sink 21 is well protected against external environmental influences. A short circuit between the two heat sinks 21, 22 can thus be avoided particularly efficiently.

The first heat sink 21 does not overlap with the second heat sink 22 in the top view of the optoelectronic semiconductor component 1 shown in FIG. 4D.

FIG. 4E shows an optoelectronic semiconductor component 1 according to an eighth exemplary embodiment, comprising a first heat sink 21, a second heat sink 22. Heat sinks 21, 22 are each provided with a metal pad 2000. A thin film insulation layer 30 extends circumferentially around the second heat sink 22 and circumferentially around the first heat sink 21. A distance between the first heat sink 21 and the second heat sink 22 corresponds in particular to a thickness 30X of the thin film insulation layer 30. The first heat sink 21 has an irregular lateral extension. The shape of the first heat sink 21 differs from the shape of the metal pad 2000 arranged above it. For example, the shape of the first heat sink 21 can thus be adapted to a geometry of an underlying geometry of the semiconductor body 10. In the top view, the first heat sink 21 and the metal pad 2000 arranged above it overlap. A short circuit between the metal pads 2000 and the first heat sink is prevented by an electrically insulating molding compound 50 not shown here.

The first heat sink 21 is therefore electrically insulated from the second heat sink 22 by means of the thin film insulation layer 30. Furthermore, both heat sinks 21, 22 are electrically insulated from the elements surrounding them. The insulation surrounding the first heat sink 21 is well protected against external environmental influences. A short circuit between the two heat sinks 21, 22 can thus be avoided particularly efficiently.

The first heat sink 21 does not overlap with the second heat sink 22 in the top view of the optoelectronic semiconductor component 1 shown in FIG. 4E.

FIG. 4F shows an optoelectronic semiconductor component 1 according to a ninth exemplary embodiment, comprising a first heat sink 21, a second heat sink 22. Heat sinks 21, 22 are each provided with a metal pad 2000. A thin film insulation layer 30 extends circumferentially around the heat sinks 21, 22 and in a meandering line between the two heat sinks 21, 22. Consequently, the first heat sink 21 is electrically insulated from the second heat sink 22 by means of the thin film insulation layer 30. Furthermore, both heat sinks 21, 22 are electrically insulated from the elements surrounding them. A distance between the first heat sink 21 and the second heat sink 22 corresponds in particular to a thickness 30X of the thin film insulation layer 30.

The first heat sink 21 and the second heat sink 22 each have projections that extend at least partially into the respective opposite heat sinks 21, 22. In other words, the first heat sink 21 and the second heat sink 22 are interlocked in a comb-like manner in a plan view. Due to a comb-like interlocking, the heat sinks 21, 22 have an increased mechanical stability.

The first heat sink 21 does not overlap with the second heat sink 22 in the top view of the optoelectronic semiconductor component 1 shown in FIG. 4F.

The present disclosure is not limited by the description based on the embodiments. Rather, the present disclosure includes any new feature as well as any combination of features, which includes in particular any combination of features in the patent claims, even if this feature or combination itself is not explicitly stated in the patent claims or embodiments.

### LIST OF REFERENCE SIGNS

1 optoelectronic semiconductor component
10 semiconductor body
10A mounting side
10B outcoupling side
21 first metallic heat sink
21A side face
22 second metallic heat sink
30 thin film insulation layer
30X thickness of the thin film insulation layer
31 passivation
41 first seed layer
42 second seed layer
43 third seed layer
50 electrically insulating molding compound
60 carrier
70 photoresist layer
101 first region
102 second region
103 active region
201 first contact
202 second contact
220 via
222 contact body
2000 metal pad
Y height
D1 first distance
D2 second distance

1. An optoelectronic semiconductor component comprising
a semiconductor body having a first region of a first conductivity, a second region of a second conductivity and an active region,
a first metallic heat sink and a second metallic heat sink, and
a thin film insulation layer, wherein
the first heat sink and the second heat sink are arranged on a mounting side of the semiconductor body,
the semiconductor body comprises a first contact and a second contact on the mounting side,
the first heat sink makes electrical contact with the first region,
the thin film insulation layer electrically insulates the first heat sink from the second heat sink, and
the thin film insulation layer is in direct contact with the first heat sink and the second heat sink.

2. The optoelectronic semiconductor component according to claim 1,
wherein the thin film insulation layer has a thickness of at most 1 μm.

3. (canceled)

4. The optoelectronic semiconductor component according to claim 1, further comprising:
metal pads arranged on the first heat sink and the second heat sink.

5. The optoelectronic semiconductor component according to claim 4,
wherein a second distance between the metal pads is at least 180 μm.

6. Optoelectronic semiconductor component according to claim 1,
wherein the first heat sink and the second heat sink have a height of between 20 μm and 500 μm.

7. The optoelectronic semiconductor component according to claim 1,
wherein the first heat sink and the second heat sink have projections which extend at least partially into the respective opposite heat sink.

8. The optoelectronic semiconductor component according to claim 1,
wherein the second heat sink makes electrical contact with the second region.

9. The optoelectronic semiconductor component according to claim 1, further comprising:
a via that extends through the second heat sink and contacts the second region.

10. The optoelectronic semiconductor component according to claim 8,
wherein the via is electrically insulated from the second heat sink.

11. The optoelectronic semiconductor component according to claim 1,
wherein a cross-sectional area of the first heat sink and of the second heat sink does not increase in each case along its entire extent in a direction transverse to a main extension plane of the semiconductor body.

12. A method for producing an optoelectronic semiconductor component comprising:
providing a semiconductor body having a first region of a first conductivity, a second region of a second conductivity and an active region, wherein the semiconductor body has a first contact and a second contact on a mounting side,
depositing a first heat sink on the mounting side of the semiconductor body, the first heat sink electrically connecting the first region,
depositing a thin film insulation layer on the mounting side, wherein the thin film insulation layer covers at least a side face of the first heat sink facing the second contact, and
depositing a second heat sink on the mounting side of the semiconductor body, wherein
a first distance between the first heat sink and the second heat sink is at most 1 μm.

13. The method for producing an optoelectronic semiconductor component according to claim 12,
wherein an electrically conductive first seed layer is applied to the mounting side of the semiconductor body before the first heat sink is deposited.

14. The method for producing an optoelectronic semiconductor component according to claim 12,
wherein the first heat sink and the second heat sink are embedded in an electrically insulating molding compound.

15. The method for producing an optoelectronic semiconductor component according to claim 12,
wherein the second heat sink is deposited after the thin film insulation layer has been deposited.

16. The method for producing an optoelectronic semiconductor component according to claim 12,
wherein the second heat sink is deposited with a lower height than the first heat sink.

17. The method for producing an optoelectronic semiconductor component according to claim 16, further comprising:
depositing a contact body is deposited on the second heat sink.

18. The method for producing an optoelectronic semiconductor component according to claim 12,
wherein the second contact is exposed after deposition of the thin film insulation layer and before deposition of the second heat sink.

19. The method for producing an optoelectronic semiconductor component according to claim 12, further comprising:
depositing a via is deposited on the mounting side of the semiconductor body before the second heat sink is deposited.

20. The method for producing an optoelectronic semiconductor component according to claim 19, further comprising:
depositing metal pads are deposited on the side of the first heat sink opposite the semiconductor body and the second heat sink.

21. An optoelectronic semiconductor component comprising:
a semiconductor body having a first region of a first conductivity, a second region of a second conductivity and an active region;
a first metallic heat sink and a second metallic heat sink; and
a thin film insulation layer,
wherein
the first heat sink and the second heat sink are arranged on a mounting side of the semiconductor body,
the semiconductor body comprises a first contact and a second contact on the mounting side,
the first heat sink makes electrical contact with the first region,
the thin film insulation layer electrically insulates the first heat sink from the second heat sink,
the thin film insulation layer is in direct contact with the first heat sink and the second heat sink, and
a first distance between the first heat sink and the second heat sink is at most 1 μm.
